(19) United States
(12) Patent Application Publication
(10) Pub. No.: US 2009/0273907 A1
(43) Pub. Date: Nov. 5, 2009

(54) CIRCUIT BOARD AND PROCESS THEREOF

(75) Inventors: Tsung-Yuan Chen, Taoyuan County (TW); Tzyy-Jang Tseng, Hsinchu (TW); Shu-Sheng Chiang, Taipei City (TW); David C. H. Cheng, Taoyuan County (TW)

Correspondence Address: J C PATENTS, 4 VENTURE, SUITE 250, IRVINE, CA, 92618, US

(73) Assignee: UNIMICRON TECHNOLOGY CORP., Taoyuan (TW)

(21) Appl. No.: 12/112,226

(22) Filed: Apr. 30, 2008

(51) Int. Cl. H05K 3/06; H05K 1/02

(52) U.S. Cl. 361/748; 29/846; 427/96.3

(57) ABSTRACT

A circuit board and process thereof are provided. The circuit board includes a dielectric layer, an active circuit, and two shielding circuits. The dielectric layer has an active surface. The active circuit is disposed on the active surface, and the shielding circuits are respectively disposed on two sides of the active circuit. The height of the shielding circuits is larger than the height of the active circuit.

### BACKGROUND OF THE INVENTION

1. Field of the Invention

The present invention relates to a circuit board and a process thereof, in particularly, to a circuit board having an electromagnetic shielding effect and a process thereof.

2. Description of Related Art

Generally speaking, a circuit board for carrying or electrically connecting a plurality of electronic components is formed by alternately laminating a plurality of patterned conductive layers and a plurality of dielectric layers. The patterned conductive layers are defined by a copper foil through a photolithography and etching process. The dielectric layers are respectively disposed between two adjacent patterned conductive layers, so as to isolate the patterned conductive layers. In addition, various electronic components (e.g. active devices or passive devices) may be further disposed on a surface of the circuit board, so as to achieve the purpose of electrical signal propagation through the circuits in the circuit board.

It is worth mentioning that, with the increase of transmission frequency of electrical signals between electronic components, electromagnetic interference and noises between main circuits aggravates. FIG. 1 is a schematic view of a conventional circuit board capable of preventing electromagnetic interference. Referring FIG. 1, in the conventional circuit board 100, in order to solve the problem that a main circuit 110 may be easily influenced by electromagnetic interference or noises from neighbouring circuits or electronic components, a lamination layer 120 for shielding the electromagnetic interference and noises is added respectively above and beneath the main circuit 110 according to the conventional art. The lamination layer 120 is a combination of a metal layer 122 with the shielding function and a dielectric layer 124. However, the entire thickness of the circuit board 100 becomes larger due to the addition of the lamination layer 120 above and beneath the main circuit 110, which goes against the development trend of light and thin electronic products.

### SUMMARY OF THE INVENTION

The present invention is directed to a circuit board and a manufacturing method thereof, in which the main circuits in the circuit board have favourable signal propagation effects, thus meeting the development of light and thin electronic products.

The present invention provides a circuit board, which includes a dielectric layer, an active circuit, and two shielding circuits. The dielectric layer comprises an active surface. The active circuit is disposed on the active surface. The shielding circuits are respectively disposed on two sides of the active circuit. The active circuit has a first height, and the shielding circuits have a second height. The second height is larger than the first height.

In an embodiment of the present invention, each of the shielding circuits includes a first shielding portion and a second shielding portion. The first shielding portions are disposed on the active surface, the second shielding portions are disposed on the first shielding portion. A height of the first shielding portions is substantially equal to the first height.

In an embodiment of the present invention, each of the shielding circuits further includes a third shielding portion buried in the dielectric layer and connected to the corresponding first shielding portion.

The present invention further provides a method of manufacturing the circuit board, which includes the following steps. First, a dielectric layer having an active surface is provided. Then, an active circuit and two shielding circuits are formed on the active surface. The shielding circuits are respectively disposed on two sides of the active circuit, and the height of the shielding circuits is larger than the height of the active circuit.

In an embodiment of the present invention, a process of forming the active circuit and the shielding circuits is an electroplating process.

In an embodiment of the present invention, the process of forming the active circuit and the shielding circuits on the active surface includes the following steps. First, a first patterned photoresist layer is formed on the active surface. The first patterned photoresist layer has a plurality of openings to expose a portion of the active surface. Then, an active circuit and two first shielding portions are formed in the openings. The first shielding portions are formed in the openings on two sides of the active circuit, and the height of the first shielding portions is substantially equal to the height of the active circuit. Then, a second patterned photoresist layer is covered on the active circuit. Afterwards, a second shielding portion is formed on each of the first shielding portions. Each of the first shielding portions and the corresponding second shielding portion constitute the shielding circuit. Thereafter, the first patterned photoresist layer and the second patterned photoresist layer are removed.

In an embodiment of the present invention, before forming the first patterned photoresist layer on the active surface, an electroplating seed layer is formed on the dielectric layer.

In an embodiment of the present invention, the process of forming the active circuit and the shielding circuits on the active surface includes the following steps. First, a first patterned photoresist layer is formed on the active surface. The first patterned photoresist layer has a plurality of openings to expose a portion of the active surface. Then, an active circuit and two first shielding portions are formed in the openings. The first shielding portions are formed in the openings on two sides of the active circuit, and the height of the first shielding portions is substantially equal to the height of the active circuit. Afterwards, the first patterned photoresist layer is removed. Thereafter, a second shielding portion is formed on each of the first shielding portions. Each of the first shielding portions and the corresponding second shielding portion constitute the shielding circuit.

In an embodiment of the present invention, the process of forming the active circuit and the first shielding portions is an electroplating process, and a process of forming the second shielding portions is an ink-jet printing process.

In an embodiment of the present invention, before forming the first patterned photoresist layer on the active surface, two third shielding portions are buried in the dielectric layer. A part of openings of the first patterned photoresist layer expose the third shielding portions, and the first shielding portions formed in the openings are connected to the third shielding portions.

In the circuit board of the present invention, the shielding circuits are respectively disposed on two sides of each of the main circuits, and the height of the shielding circuits is larger than the height of the main circuit. The shielding circuits may effectively solve the problem of electromagnetic interference between the main circuits, and thus the main circuits have favourable signal transmission quality. It is worth mentioning that the present invention can effectively solve the problem of electromagnetic interference between main circuits and also makes the circuit board meet the development trend of light and thin electronic products.

In order to make the aforementioned and other objects, features and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a conventional circuit board capable of preventing electromagnetic interference.

FIG. 2 is a flow chart illustrating processes of manufacturing a circuit board according to an embodiment of the present invention.

FIGS. 3A to 3E are three-dimensional views illustrating processes of manufacturing a circuit board according to an embodiment of the present invention.

FIGS. 4A and 4B show a method of forming a second shielding portion according to another embodiment of the present invention.

FIGS. 5A to 5E are three-dimensional views illustrating processes of manufacturing a circuit board according to a further embodiment of the present invention.

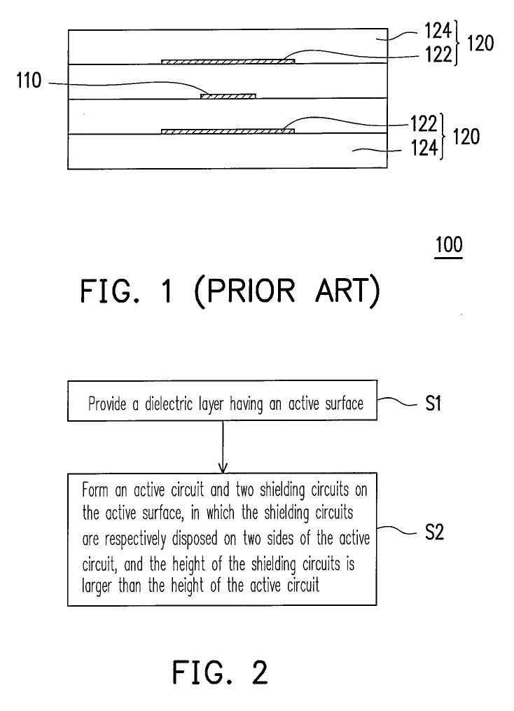

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

FIG. 2 is a flow chart illustrating processes of manufacturing the circuit board according to an embodiment of the present invention. Referring to FIG. 2, the method of manufacturing a circuit board in this embodiment includes the following steps. First, in Step S1, a dielectric layer having an active surface is provided. Then, in Step S2, an active circuit and two shielding circuits are formed on the active surface. The shielding circuits are respectively disposed on two sides of the active circuit, and the height of the shielding circuits is larger than the height of the active circuit. In order to clarify the method of manufacturing a circuit board as shown in FIG. 2, detailed descriptions will be made to this embodiment with reference to the three-dimensional view below.

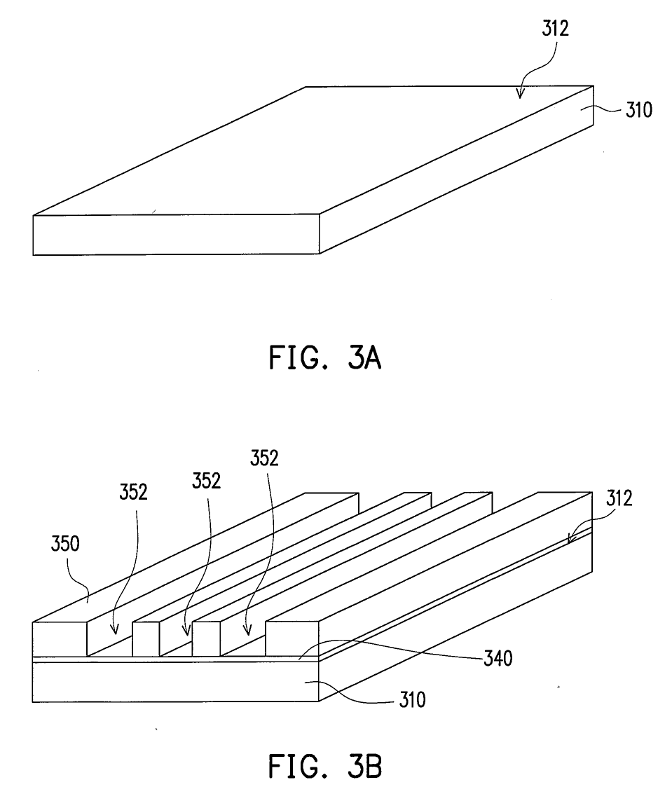

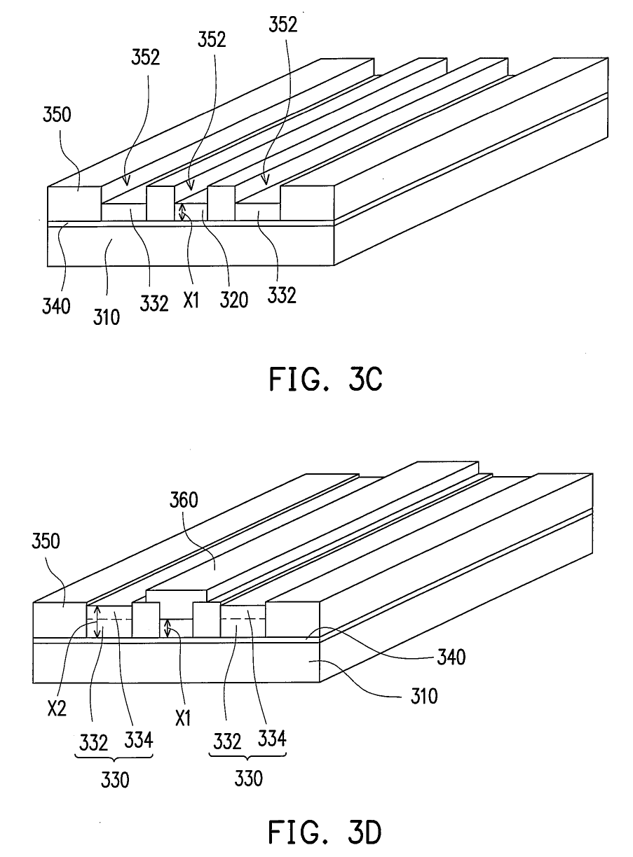

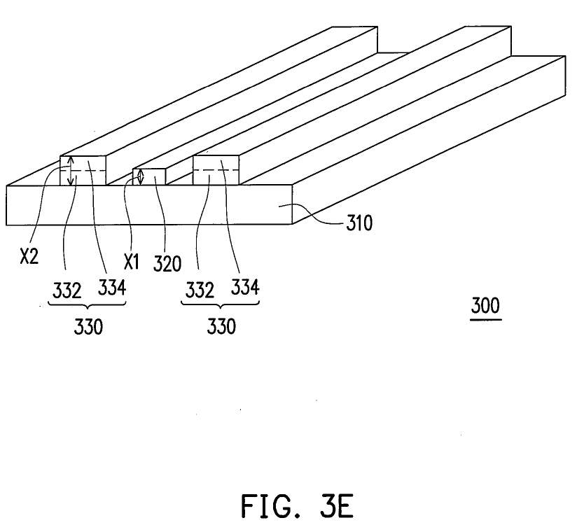

FIGS. 3A to 3E are three-dimensional views illustrating processes of manufacturing a circuit board according an embodiment of the present invention. First, referring to 3A, a dielectric layer 310 having an active surface 312 is provided. Then, referring to FIGS. 3B to 3E, an active circuit 320 and two shielding circuits 330 are formed on the active surface 312. In detail, in this embodiment, for example, an electroplating seed layer 340 is first formed on the active surface 312, and a first patterned photoresist layer 350 is formed on the electroplating seed layer 340 (as shown in FIG. 3B), for facilitating the following electroplating process. In this embodiment, the first patterned photoresist layer 350, for example, has a plurality of openings 352 to expose a portion of the electroplating seed layer 340 on the active surface 312.

After forming the electroplating seed layer 340 and the first patterned photoresist layer 350 on the active surface 312, an active circuit 320 and two first shielding portions 332 are formed in the openings 352 by using an electroplating process (as shown in FIG. 3C). In this embodiment, the first shielding portions 332 are formed in the openings 352 on two sides of the active circuit 320. The active circuit 320 has a first height X1 which is substantially equal to the height of the first shielding portions 332. Afterwards, a second patterned photoresist layer 360 is covered on the active circuit 320 and the electroplating process is used again to form second shielding portions 334 on the first shielding portions 332 in the above openings (as shown in FIG. 3D). Each of the first shielding portions 332 and the corresponding second shielding portion 334 constitute a shielding circuit 330. The shielding circuits 330 have a second height X2 which is larger than the height X1 of the active circuit. Definitely, in other embodiments, other suitable processes may also be adopted to form the active circuit 320, the first shielding portions 332, and the second shielding portions 334 in the openings, which will not be limited in the present invention.

Furthermore, after the electroplating process is used again to form a second shielding portion 334 on each of the first shielding portions 332, a part of the second patterned photoresist layer, the first patterned photoresist layer, and the electroplating seed layer covered by the first patterned photoresist layer is removed (as shown in FIG. 3E). In this manner, shielding circuits 330 are respectively formed on two sides of the active circuit 320. In this embodiment, the manufacturing of the circuit board 300 is completed. Since one shielding circuit 330 is formed on each side of the active circuit 320, and the second height X2 of the shielding circuit 330 is larger than the first height X1 of the active circuit, the electromagnetic effect generated by other active circuits (not shown) or electronic components (not shown) adjacent to the active circuit 320 is not liable to interfere with the active circuit 320. In other words, the circuit board of this embodiment has a better signal transmission quality. Moreover, since the shielding circuits 330 are respectively disposed on two sides of the active circuit 320 in this embodiment, i.e., the shielding circuits 330 and the active circuit 320 are all disposed on the active surface 312, the whole circuit board 300 has a smaller thickness or height.

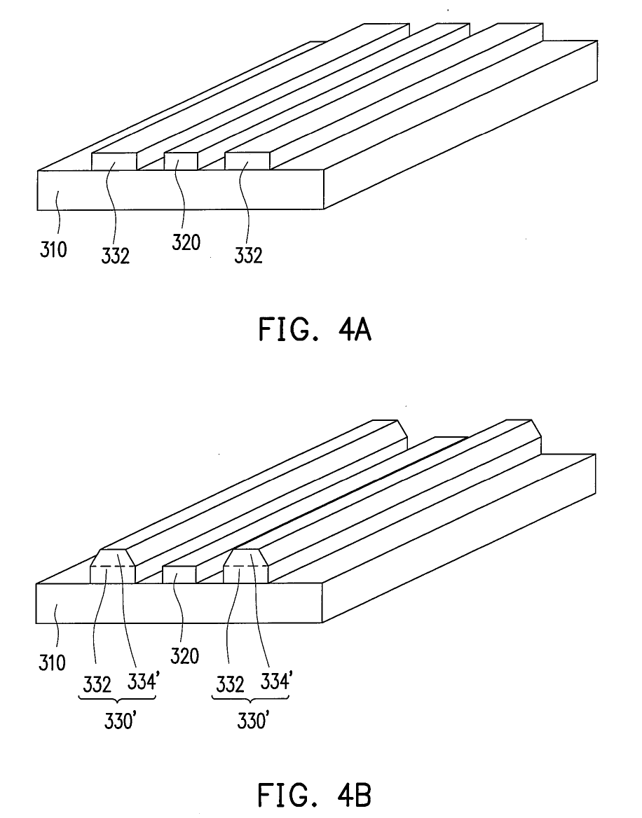

In view of the above, in addition to the electroplating process for forming the second shielding portions, the second shielding portion may be formed on each of the first shielding portions through an ink-jet printing process. FIGS. 4A and 4B show a method of forming a second shielding portion according to another embodiment of the present invention. Referring to FIG. 4A, after the step (forming the active circuit 320 and the first shielding portions 332 in the openings) in FIG. 3C is completed, in this embodiment, the first patterned photoresist layer and the electroplating seed layer covered by the first patterned photoresist layer may be first removed. Afterwards, as shown in FIG. 4B, a second shielding portion 334′ is formed on each of the first shielding portions 332 through the inkjet printing process. The second shielding portions 334′ are, for example, copper pastes, and each of the first shielding portions 332 and the corresponding second shielding portion 334′ may also constitute a shielding circuit 330′.

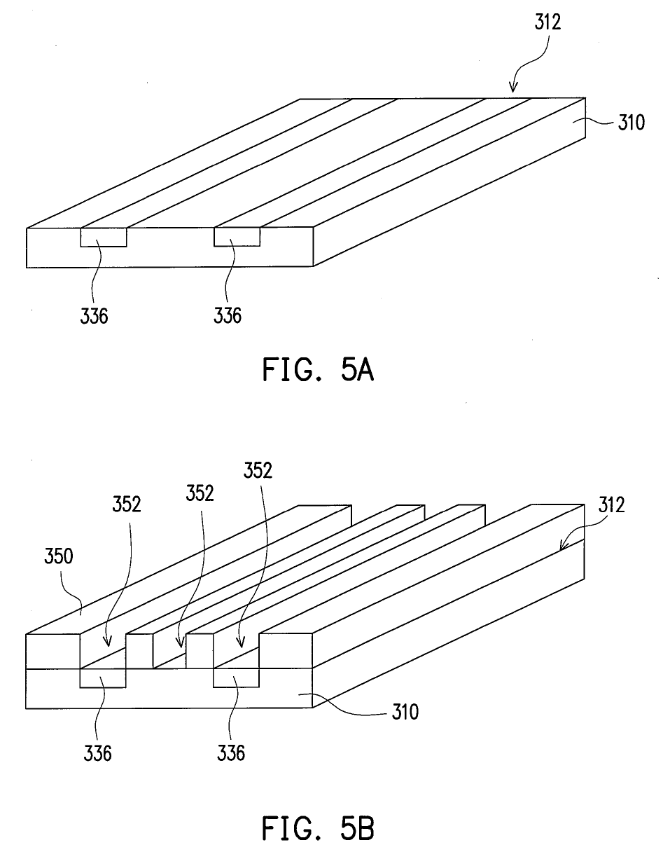

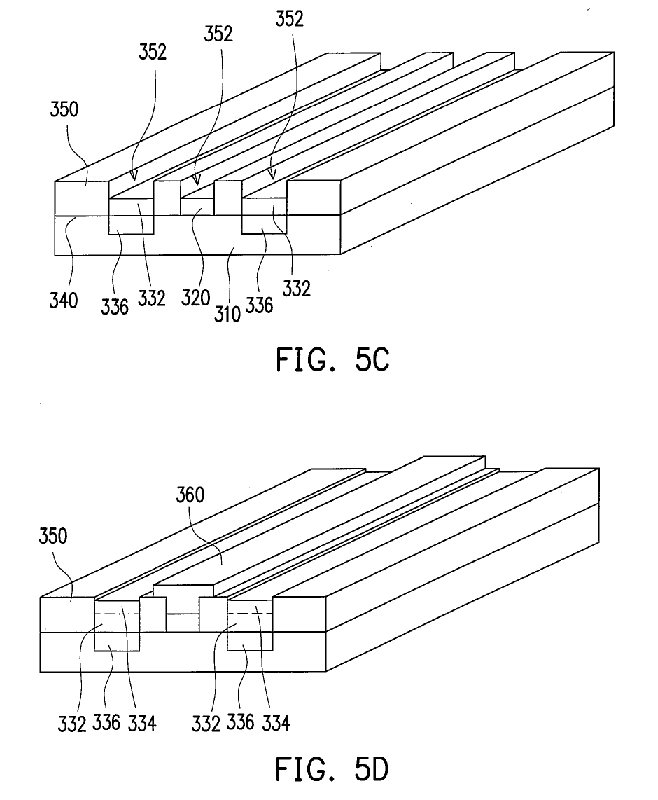

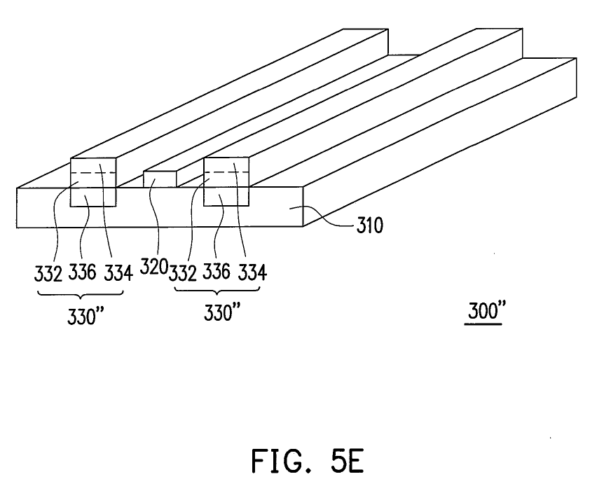

FIGS. 5A to 5E are three-dimensional views illustrating processes of manufacturing a circuit board according to a further embodiment of the present invention. The processes of manufacturing a circuit board as shown in FIGS. 5A to 5E are similar to those in FIGS. 3A-3E, and only the difference is described. In this embodiment, before the first patterned photoresist layer is formed on the active surface 312, two third shielding portions 336 are buried in the dielectric layer 310 in advance (as shown in FIG. 5A). After the first patterned photoresist layer 350 is formed on the active surface 312 (as shown in FIG. 5 B), a part of the openings 352 of the first patterned photoresist layer 350 expose the third shielding portions 336 and the first shielding portions 332 formed in the openings will be connected with the third shielding portions 336 (as shown in FIG. 5C). Then, the steps of manufacturing the second shielding portions 334 and removing the photoresist layers are performed (as shown in FIGS. 5D to 5E), thereby finishing another circuit board 300″. The third shielding portions 336, the first shielding portions 332, and the second shielding portions 334 constitute other shielding circuits 330″.

In view of the above, in the present invention, the shielding circuits having a height larger than that of the active circuit are respectively disposed on two sides of each of the main circuits. Therefore, the electromagnetic effect generated by the electronic components or other active circuits adjacent to the active circuit will not influence the signal transmission quality of the active circuit. That is, the active circuit has a better signal transmission quality. Furthermore, since the shielding circuits are disposed on two sides of the active circuit in the present invention, as compared with the conventional art that the lamination layers are added above or beneath the main circuits to shield the electromagnetic interference and noises, the whole circuit board of the present invention has a small thickness or height. In other words, the circuit board of the present invention has a better signal propagation effect and can also meet the development trend of light and thin electronic components.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit board, comprising:
a dielectric layer, comprising an active surface;
an active circuit, disposed on the active surface, wherein the active circuit is provided with a first height; and
two shielding circuits, respectively disposed on two sides of the active circuit, wherein each of the shielding circuits is provided with a second height, and the second height is larger than the first height.

2. The circuit board as claimed in claim 1, wherein each of the shielding circuits comprises a first shielding portion and a second shielding portion, the first shielding portions are disposed on the active surface, the second shielding portions are disposed on the first shielding portions, and the height of the first shielding portions is substantially equal to the first height.

3. The circuit board as claimed in claim 2, wherein each of the shielding circuit further comprises a third shielding portion buried in the dielectric layer and connected with the first shielding portion.

4. A method of manufacturing a circuit board, comprising:
providing a dielectric layer comprising an active surface; and
forming an active circuit and two shielding circuits on the active surface, wherein the shielding circuits are respectively disposed on two sides of the active circuit, and a height of the shielding circuits is larger than a height of the active circuit.

5. The method of manufacturing a circuit board as claimed in claim 4, wherein a process of forming the active circuit and the shielding circuits is an electroplating process.

6. The method of manufacturing a circuit board as claimed in claim 4, wherein a process of forming the active circuit and the shielding circuits on the active surface comprises:
forming a first patterned photoresist layer on the active surface, wherein the first patterned photoresist layer comprises a plurality of openings to expose a portion of the active surface;
forming the active circuit and two first shielding portions in the openings, wherein the first shielding portions are formed in the openings on two sides of the active circuit and a height of the first shielding portions is substantially equal to the height of the active circuit;
covering a second patterned photoresist layer on the active circuit;
forming a second shielding portion on each of the first shielding portions, wherein each of the first shielding portions and a corresponding second shielding portion constitute the shielding circuit; and
removing the first patterned photoresist layer and the second patterned photoresist layer.

7. The method of manufacturing a circuit board as claimed in claim 6, before forming the first patterned photoresist layer on the active surface, further comprising forming an electroplating seed layer on the dielectric layer.

8. The manufacturing method as claimed in claim 4, wherein a process of forming the active circuit and the shielding circuits on the active surface comprises:
forming a first patterned photoresist layer on the active surface, wherein the first patterned photoresist layer comprises a plurality of openings to expose a portion of the active surface;
forming the active circuit and two first shielding portions in the openings, wherein the first shielding portions are formed in the openings on two sides of the active circuit, and a height of the first shielding portions is substantially equal to the height of the active circuit;
removing the first patterned photoresist layer; and
forming a second shielding portion on the first shielding portion, wherein each of the first shielding portions and a corresponding second shielding portion constitute the shielding circuit.

9. The method of manufacturing a circuit board as claimed in claim 8, wherein the process of forming the active circuit and the first shielding portions is an electroplating process, and a process of forming the second shielding portions is an ink-jet printing process.

10. The method of manufacturing a circuit board as claimed in claim 6, before forming the first patterned photoresist layer on the active surface, further comprising burying two third shielding portions in the dielectric layer, wherein a part of openings of the first patterned photoresist layer expose the third shielding portions, and the first shielding portions formed in the openings are connected with the third shielding portions.
